(19) United States
(12) Patent Application Publication
(10) Pub. No.: US 2026/0164846 A1
(43) Pub. Date: Jun. 11, 2026

(54) METHOD FOR COUPLING HEMISPHERICAL LENS TO TERAHERTZ OPTOELECTRONIC CHIP

(71) Applicant: Wuhan Huazhong Kuangteng Optical Tech Co., Ltd., Wuhan City (CN)

(72) Inventors: Zitong ZHANG, Wuhan City (CN); Chensheng WANG, Wuhan City (CN); Yufei GUO, Wuhan City (CN); Tianyi WANG, Wuhan City (CN)

(73) Assignee: Wuhan Huazhong Kuangteng Optical Tech Co., Ltd., Wuhan City (CN)

(21) Appl. No.: 19/374,891

(22) Filed: Oct. 30, 2025

(30) Foreign Application Priority Data
Dec. 6, 2024 (CN) 202411790792.7

(51) Int. Cl. H10F 77/40

(52) U.S. Cl. CPC H10F 77/413

(57) ABSTRACT

Provided is a method for coupling a hemispherical lens to a terahertz optoelectronic chip. First, a printed circuit board and a hemispherical lens are ultrasonically cleaned. Then, a flat side of the hemispherical lens is placed against a back side of the printed circuit board, and UV glue is applied at the junction and cured with a UV lamp. The printed circuit board and the hemispherical lens are fixed on a base. A two-dimensional imaging instrument is used to align a center hole of the terahertz optoelectronic chip with a center of the hemispherical lens. Finally, a chip mounter is used to complete the coupling of the terahertz optoelectronic chip and the hemispherical lens. The coupling method of this application can be used in a fabrication process of transmission or reception chips, with a high degree of standardization, good compatibility, and high repeatability, making it suitable for large-scale manufacturing.

### CROSS REFERENCE TO RELATED APPLICATION

This patent application claims the benefit and priority of Chinese Patent Application No. 202411790792.7, filed with the China National Intellectual Property Administration on Dec. 6, 2024, the disclosure of which is incorporated by reference herein in its entirety as part of the present application.

### TECHNICAL FIELD

The present disclosure relates to the technical field of terahertz optoelectronic chips, and in particular, to a packaging and manufacturing method for coupling a hemispherical lens to a chip.

### BACKGROUND

The terahertz (THz) band generally refers to electromagnetic waves with a frequency range of 0.1 to 10 THz. Terahertz waves have broad applications in communications, military, astronomy, and other fields.

In the field of communications, terahertz space communication combines the advantages of laser communication and microwave communication. Compared with laser communication, terahertz communication has a wider beam, making it easier to align the receiving end, and lower quantum noise; compared with the microwave band, the antenna system can be miniaturized and planarized. Due to channel attenuation in the atmosphere, terahertz communication is more suitable for satellite space communication and can be used to build broadband mobile high-speed information networks between satellites, between satellites and the ground, and in local area networks.

In the military field, terahertz waves can penetrate the “blackout” zone. For high-speed near-space vehicles and re-entry vehicles (such as missiles and spacecraft), plasma with a frequency of several tens of GHz is generated around the vehicle, forming a “blackout” communication blind zone that causes rapid attenuation and interruption of radio telemetry signals. Terahertz wave communication is the only communication means capable of penetrating the plasma.

In the field of astronomical detection, radiation in the terahertz band accounts for more than 50% of the total radiation from the Milky Way. Therefore, terahertz space detection is of great value for inferring stellar evolution and determining the composition and state of nebular gases. Devices that generate terahertz waves include photoconductive and photodiode types. For photoconductive types, commonly used substrates include GaAs in the 800 nm band and InGaAs in the 1550 nm band.

Due to the significant difference in the refractive index of terahertz-band electromagnetic waves between common optoelectronic chip substrates and air, most terahertz waves in the substrate cannot be emitted into the air due to total internal reflection. By coupling a hemispherical lens with a suitable refractive index onto the optoelectronic chip, the emission or reception efficiency of terahertz waves can be greatly improved, thereby enhancing device performance.

### SUMMARY

To increase the strength of terahertz signals emitted or received by terahertz optoelectronic chips, the present disclosure proposes a method for coupling a hemispherical lens to a terahertz optoelectronic chip.

The technical solution adopted by the present disclosure to solve the technical problems is: A method for coupling a hemispherical lens to a terahertz optoelectronic chip, including the following steps:
a) providing hollowed-out portions at a center and edges of a printed circuit board for placing a terahertz optoelectronic chip and observing an edge of the hemispherical lens; sequentially placing the printed circuit board and the hemispherical lens in acetone and isopropyl alcohol solutions for 10-minute ultrasonic cleaning, and then blowing surfaces dry with a nitrogen gun;
b) placing a front side of the printed circuit board downward; placing a flat side of the hemispherical lens against a back side of the printed circuit board, aligning the hemispherical lens with a positioning silkscreen ring; applying an appropriate amount of UV glue at a junction between the hemispherical lens and the printed circuit board, and irradiating with a UV lamp for 3 to 5 min to fully cure the UV glue;
c) placing the front side of the printed circuit board upward, and fixing the hemispherical lens in a base, with a spherical side of the hemispherical lens facing downward, and then placing the hemispherical lens with the base under a two-dimensional imaging instrument;
d) locating the edge of the hemispherical lens at the hollowed-out portions of the printed circuit board by using the two-dimensional imaging instrument; determining a center of the hemispherical lens using a three-point method; and placing a center hole of the terahertz optoelectronic chip aligned with the center of the hemispherical lens, such that a center of a chip pattern is aligned with the center of the hemispherical lens;
e) aligning a placement head of a chip mounter with the terahertz optoelectronic chip; applying a constant pressure to the terahertz optoelectronic chip and holding for a period; during the pressure application, simultaneously applying an appropriate amount of UV glue at a junction between the terahertz optoelectronic chip and the hemispherical lens, and irradiating with the UV lamp for 3 to 5 min to fully cure the UV glue; and removing the pressure after the UV glue is cured;
f) finally, placing the sample in a hot air oven and baking at 50° C. for 12 h for aging treatment of the UV glue, completing the coupling of the terahertz optoelectronic chip and the hemispherical lens, where a main structure after coupling includes the printed circuit board, the terahertz optoelectronic chip, and the hemispherical lens.

In the method for coupling a hemispherical lens to a terahertz optoelectronic chip, step a) further includes providing fixing holes at an outer side of the printed circuit board for fixing to the base.

In the method for coupling a hemispherical lens to a terahertz optoelectronic chip, the pressure in step e) is a pressure corresponding to 8 to 10 atmospheres.

In the method for coupling a hemispherical lens to a terahertz optoelectronic chip, the hemispherical lens is a standard hemisphere, a hyper-hemisphere, or a hypo-hemisphere, and does not require an additional boss design.

In the method for coupling a hemispherical lens to a terahertz optoelectronic chip, the hemispherical lens is made of high-resistivity silicon, High-Density Polyethylene (HDPE), or polymethylpentene (PMP).

In the method for coupling a hemispherical lens to a terahertz optoelectronic chip, a substrate material of the terahertz optoelectronic chip is GaAs or InP/InGaAs.

The present disclosure has the following beneficial effects: The hemispherical lens is adhered to the back side of the printed circuit board, and the placement head of the chip mounter is used to apply a constant pressure to couple the chip placed on the lens; UV glue is used for bonding to form a complete terahertz transmission or reception device. Thus, the present disclosure significantly enhances the efficiency of the chip in emitting or absorbing terahertz waves.

### BRIEF DESCRIPTION OF THE DRAWINGS

FIG. 1 is a three-dimensional schematic structural diagram of an apparatus used in the method of the present disclosure;

FIG. 2 is a schematic side view of the apparatus during coupling;

FIG. 3 is a top view of the apparatus after coupling is completed;

FIG. 4 is a side view of the apparatus after coupling is completed;

FIG. 5 is a graph showing terahertz electric field strength versus time tested based on a terahertz time-domain spectrometer; and

FIG. 6 is a frequency spectrum obtained based on a fast Fourier transform.

Reference numerals: 1—terahertz optoelectronic chip; 2—base; 3—hollowed-out portion; 4—fixing hole; 5—hemispherical lens; 6—printed circuit board.

### DETAILED DESCRIPTION OF THE EMBODIMENTS

The following describes the implementation of the present disclosure in detail, clearly, and completely with reference to specific embodiments and accompanying drawings.

A method for coupling a hemispherical lens to a terahertz optoelectronic chip disclosed in the present disclosure is implemented using an apparatus that includes a printed circuit board 6 with hollowed-out portions 3 and fixing holes 4, a custom base 2, a hemispherical lens 5, a terahertz optoelectronic chip 1, a chip mounter, etc. Steps are as follows.
a) Provide the hollowed-out portions 3 at a center and edges of the printed circuit board 6 for placing the terahertz optoelectronic chip 1 and observing an edge of the hemispherical lens 5; sequentially place the printed circuit board 6 and the hemispherical lens 5 in acetone and isopropyl alcohol solutions for 10-minute ultrasonic cleaning, and then blow surfaces dry with a nitrogen gun.

In this step, the hollowed-out portions 3 are primarily used for observing the edge of the hemispherical lens 5, and three points on the circular edge can be used to locate the center of the circle. The advantage of this design is that it facilitates aligning the center of the terahertz optoelectronic chip 1 with the center of the hemispherical lens 5 without the need for custom positioning fixtures. This step also involves forming the fixing holes 4 on an outer side of the printed circuit board 6 for fixing to the base 2.

The hemispherical lens 5 has a shape of a standard hemisphere, hyper-hemisphere, or hypo-hemisphere, and requires no additional boss design. The hemispherical lens 5 is made of high-resistivity silicon, HDPE, or polymethylpentene (PMP). A substrate material of the terahertz optoelectronic chip 1 is GaAs or InP/InGaAs.
b) Place a front side of the printed circuit board 6 downward; place a flat side of the hemispherical lens 5 against a back side of the printed circuit board 6, aligning the hemispherical lens 5 with a positioning silkscreen ring; apply an appropriate amount of UV glue at a junction between the hemispherical lens 5 and the printed circuit board 6, and irradiate with a UV lamp for 3 to 5 min to fully cure the UV glue. The UV glue can rapidly cure under UV irradiation and has low shrinkage.

In this step, the UV glue is typically a relatively viscous transparent liquid that solidifies when exposed to sufficiently intense UV light. The advantages of the UV glue as a binder are good fluidity, low shrinkage, strong adhesion to materials such as plastics and glass, and suitability for bonding small-sized chips.

In this step, the hemispherical lens 5 is fixed to the back side of the printed circuit board 6 using the UV glue. The advantage of this design is that the method is compatible with most types of hemispherical lenses.
c) Place the front side of the printed circuit board 6 upward, and fix the hemispherical lens 5 in a base 2, with a spherical side of the hemispherical lens 5 facing downward, and then place the hemispherical lens 5 with the base 2 under a two-dimensional imaging instrument.
d) Locate the edge of the hemispherical lens 5 at the hollowed-out portions 3 of the printed circuit board 6 by using the two-dimensional imaging instrument; determine a center of the hemispherical lens 5 using a three-point method; and place a center hole of the terahertz optoelectronic chip 1 aligned with the center of the hemispherical lens 5, such that a center of a chip pattern is aligned with the center of the hemispherical lens 5.
e) Align a placement head of a chip mounter with the terahertz optoelectronic chip 1; apply a constant pressure (typically corresponding to 8 to 10 atmospheres) to the terahertz optoelectronic chip 1 and hold for a period; during the pressure application, simultaneously apply an appropriate amount of UV glue at a junction between the terahertz optoelectronic chip 1 and the hemispherical lens 5, and irradiate with the UV lamp for 3 to 5 min to fully cure the UV glue; and remove the pressure after the UV glue is cured.

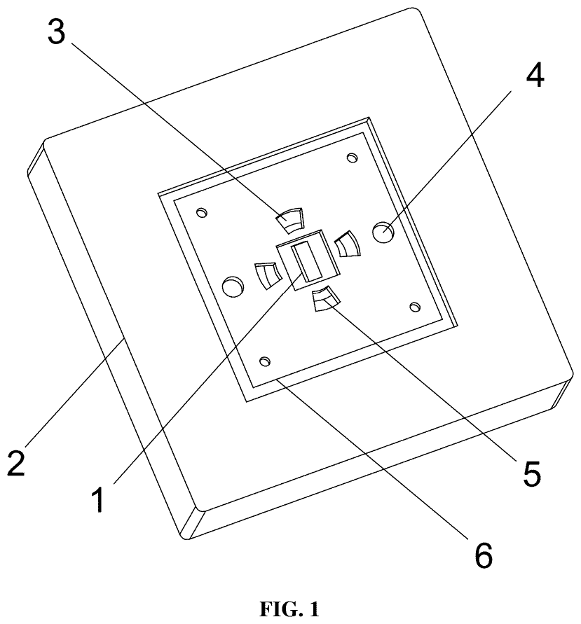

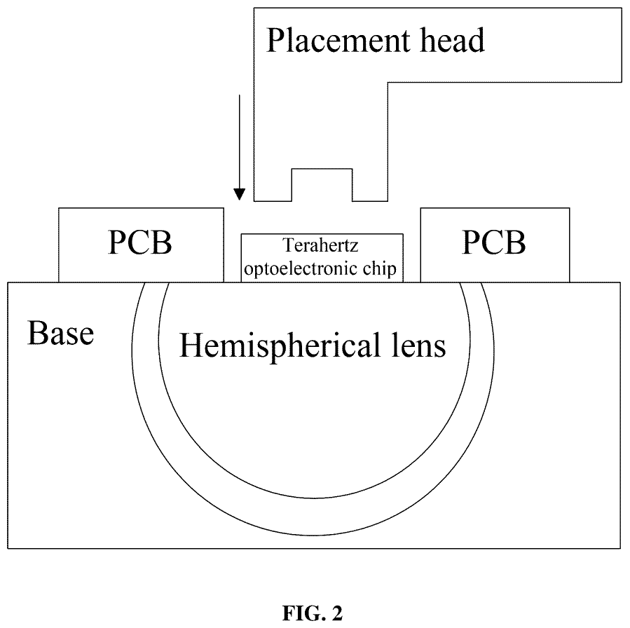

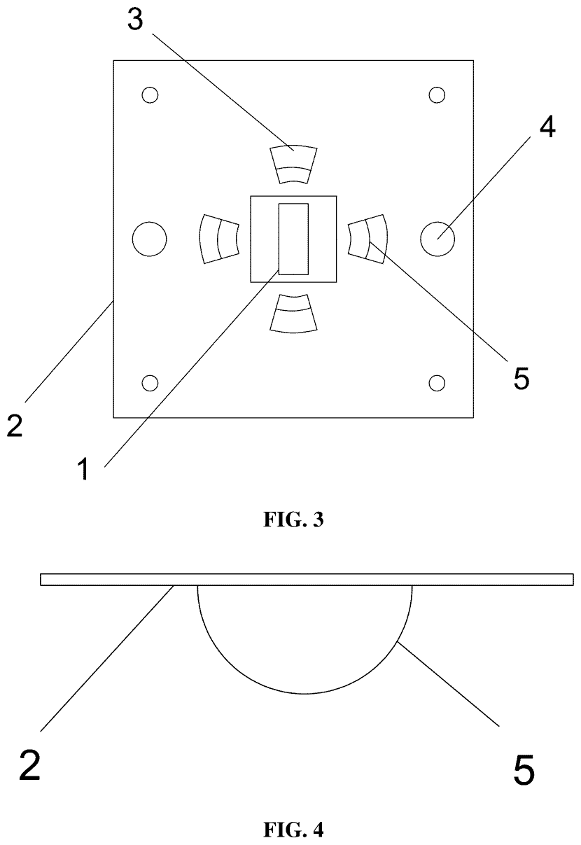

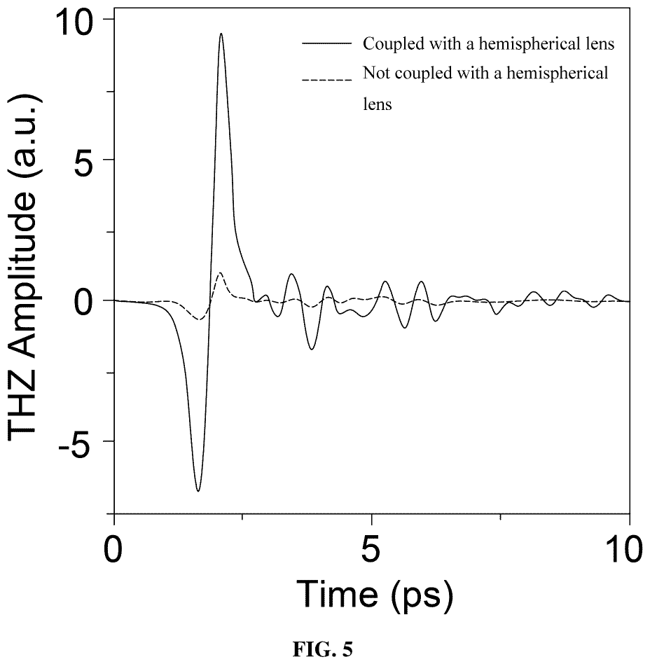

The chip mounter in this step can apply a constant downward pressure in the vertical direction and maintain it for a specific period. The advantage of using a chip mounter for coupling is that it can apply a precisely determined pressure. This has two benefits: first, it ensures process stability and repeatability; second, it allows applying different pressures for chips of different sizes to achieve similar coupling effects.
f) Finally, place the sample in a hot air oven and bake at 50° C. for 12 h for aging treatment of the UV glue, completing the coupling of the terahertz optoelectronic chip 1 and the hemispherical lens 5, where a main structure after coupling includes the printed circuit board 6, the terahertz optoelectronic chip 1, and the hemispherical lens 5, as shown in FIG. 1 and FIG. 2. The hemispherical lens 5 is fixed on the printed circuit board 6, and the terahertz optoelectronic chip 1 is fixed on the hemispherical lens 5, as shown in FIG. 3 and FIG. 4.

The focusing effect of the hemispherical lens can effectively concentrate terahertz waves, significantly enhancing the emission power or responsivity of terahertz waves. The coupling method of the present disclosure first uses an imaging instrument for center positioning and then leverages the ability of the chip mounter to apply constant pressure to press the optoelectronic chip onto the hemispherical lens, minimizing interfacial gaps. Devices prepared through this process were obtained after property characterization using the following equipment.

A light source used in the experiment was a mode-locked femtosecond laser developed by Daheng New Epoch Technology, with a central wavelength of 800 nm, pulse width less than 50 fs, repetition rate of 80 MHz, and maximum output power of 400 mW. The laser was first split into pump light and probe light. The pump light was focused onto the terahertz optoelectronic chip via a variable optical attenuator and a focusing lens. The terahertz pulses emitted by the terahertz optoelectronic chip were focused onto a ZnTe crystal via two off-axis parabolic mirrors. The probe light was also focused onto the ZnTe crystal via an optical delay stage. Under the modulation of the terahertz waves, the ZnTe crystal altered the polarization state of the pulsed laser, which was detected by a balanced detector via a Wollaston prism. A lock-in amplifier amplified and recorded a voltage signal output by the balanced detector, and output a sinusoidal voltage signal of the same frequency. This signal was amplified and applied to electrodes at both ends of the terahertz optoelectronic chip. The lock-in frequency was set to 8.337 kHz, the integration time was 30 ms, and all tests were conducted in an atmospheric environment.

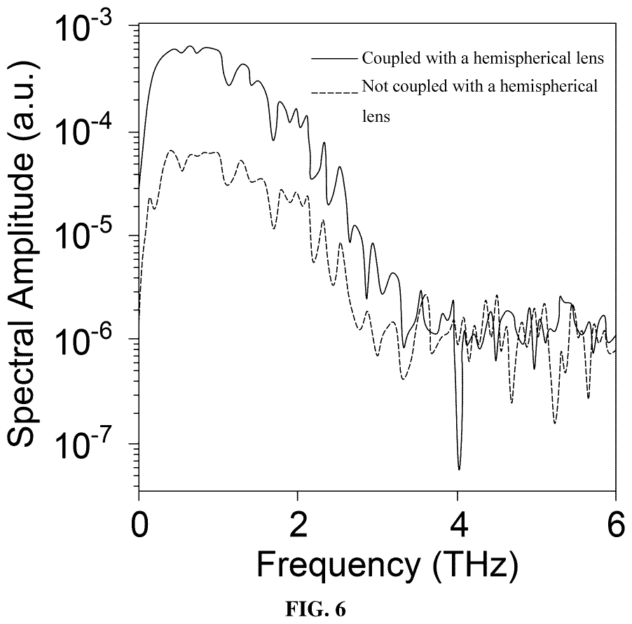

The performance of the terahertz optoelectronic chip device coupled with a hemispherical lens prepared using the above method is illustrated in FIG. 5 and FIG. 6: In FIG. 5, the dashed line represents the terahertz radiation intensity of a sample not coupled with a hemispherical lens, and the solid line represents the terahertz radiation intensity of a sample with a hemispherical lens coupled using the method of the present disclosure. In FIG. 6, the dashed line represents the terahertz radiation intensity of a sample not coupled with a hemispherical lens, and the solid line represents the terahertz radiation intensity of a sample with a hemispherical lens coupled using the method of the present disclosure. The terahertz radiation intensity increased by approximately 5 times under the same laser power and bias voltage.

The above embodiments merely exemplify the principles and efficacy of the present disclosure, as well as some applied embodiments. For those of ordinary skill in the art, various modifications and improvements can be made without departing from the creative concept of the present disclosure, and such modifications and improvements all fall within the protection scope of the present disclosure.

What is claimed is:

1. A method for coupling a hemispherical lens to a terahertz optoelectronic chip, comprising the following steps:
a) providing hollowed-out portions (3) at a center and edges of a printed circuit board (6);
sequentially placing the printed circuit board (6) and a hemispherical lens (5) in acetone and isopropyl alcohol solutions for ultrasonic cleaning, and then blowing surfaces dry with a nitrogen gun;
b) placing a front side of the printed circuit board (6) downward; placing a flat side of the hemispherical lens (5) against a back side of the printed circuit board (6); applying ultraviolet (UV) glue at a junction between the hemispherical lens (5) and the printed circuit board (6), and irradiating with a UV lamp to fully cure the UV glue;
c) placing the front side of the printed circuit board (6) upward, and fixing the hemispherical lens (5) in a base (2), with a spherical side of the hemispherical lens (5) facing downward, and then placing the hemispherical lens (5) with the base (2) under a two-dimensional imaging instrument;
d) locating an edge of the hemispherical lens (5) at the hollowed-out portions (3) by using the two-dimensional imaging instrument; determining a center of the hemispherical lens (5) using a three-point method; and placing a center hole of the terahertz optoelectronic chip (1) aligned with the center of the hemispherical lens (5);
e) aligning a placement head of a chip mounter with the terahertz optoelectronic chip (1);
applying a constant pressure to the terahertz optoelectronic chip (1); simultaneously applying UV glue at a junction between the terahertz optoelectronic chip (1) and the hemispherical lens (5), and irradiating with the UV lamp to fully cure the UV glue; and
f) placing the terahertz optoelectronic chip (1) and the hemispherical lens (5) into a hot air oven for aging treatment, to complete coupling of the terahertz optoelectronic chip (1) and the hemispherical lens (5).

2. The method for coupling a hemispherical lens to a terahertz optoelectronic chip according to claim 1, wherein the step a) further comprises providing fixing holes (4) at an outer side of the printed circuit board (6) for fixing to the base (2).

3. The method for coupling a hemispherical lens to a terahertz optoelectronic chip according to claim 2, wherein the pressure in the step e) is a pressure corresponding to 8 to 10 atmospheres.

4. The method for coupling a hemispherical lens to a terahertz optoelectronic chip according to claim 1, wherein the hemispherical lens (5) is a standard hemisphere, a hyper-hemisphere, or a hypo-hemisphere.

5. The method for coupling a hemispherical lens to a terahertz optoelectronic chip according to claim 1, wherein the hemispherical lens (5) is made of high-resistivity silicon, High-Density Polyethylene (HDPE), or polymethylpentene (PMP).

6. The method for coupling a hemispherical lens to a terahertz optoelectronic chip according to claim 1, wherein a substrate material of the terahertz optoelectronic chip (1) is GaAs or InP/InGaAs.

7. The method for coupling a hemispherical lens to a terahertz optoelectronic chip according to claim 2, wherein the hemispherical lens (5) is a standard hemisphere, a hyper-hemisphere, or a hypo-hemisphere.

8. The method for coupling a hemispherical lens to a terahertz optoelectronic chip according to claim 3, wherein the hemispherical lens (5) is a standard hemisphere, a hyper-hemisphere, or a hypo-hemisphere.

9. The method for coupling a hemispherical lens to a terahertz optoelectronic chip according to claim 2, wherein the hemispherical lens (5) is made of high-resistivity silicon, High-Density Polyethylene (HDPE), or polymethylpentene (PMP).

10. The method for coupling a hemispherical lens to a terahertz optoelectronic chip according to claim 3, wherein the hemispherical lens (5) is made of high-resistivity silicon, High-Density Polyethylene (HDPE), or polymethylpentene (PMP).

11. The method for coupling a hemispherical lens to a terahertz optoelectronic chip according to claim 2, wherein a substrate material of the terahertz optoelectronic chip (1) is GaAs or InP/InGaAs.

12. The method for coupling a hemispherical lens to a terahertz optoelectronic chip according to claim 3, wherein a substrate material of the terahertz optoelectronic chip (1) is GaAs or InP/InGaAs.
